(19) United States
(12) Patent Application Publication
(10) Pub. No.: US 2024/0195431 A1
(43) Pub. Date: Jun. 13, 2024

(54) Digital to analogue voltage converter

(71) Applicant: ams International AG, Jona (CH)

(72) Inventors: Massimo RIGO, Trieste (IT); Fridolin MICHEL, Au (CH)

(21) Appl. No.: 18/554,480

(22) PCT Filed: Apr. 8, 2022
(86) PCT No.: PCT/EP2022/059447

§ 371 Date: Oct. 9, 2023

(30) Foreign Application Priority Data
Apr. 9, 2021 (GB) 2105111.5

(51) Int. Cl. H03M 1/76

(52) U.S. Cl. CPC H03M 1/765

(57) ABSTRACT

A digital to analogue voltage converter (DAC) comprising: a first resistor string having a plurality of resistors; and a plurality of DAC stages, each DAC stage coupled to said first resistor string and comprising: a voltage buffer; a first switching stage coupled to the first resistor string, the first switching stage configured to provide an input to the voltage buffer in dependence on receiving a first sub-word of a digital input; a second resistor string having one or more resistors, wherein a first end of the second resistor string is coupled to a current source and a second end of the second resistor string is coupled to an output of the voltage buffer; and a second switching stage coupled to the second resistor string and configured to provide an output of the DAC stage in dependence on receiving a second sub-word of the digital input.

### RELATED APPLICATION(S)

This application is a US National Stage Application of International Application PCT/EP2022/059447, filed on 8 Apr. 2022, and claims priority under 35 U.S.C. § 119(a) and 35 U.S.C. § 365(b) from GB Patent Application 2105111.5, filed on 9 Apr. 2021, the contents of which are incorporated herein by reference in their entirety.

### TECHNICAL FIELD

The disclosure relates to a digital to analogue voltage converter. The disclosure further relates to photon counting circuitry, and a device for medical diagnostics, comprising the digital to analogue voltage converter

### BACKGROUND

Digital to Analog Converters (DAC) are employed to represent digital values in the analogue domain. One category of DACs is represented by resistive DACs, which resort to a matched resistor string connected between two reference voltages to generate a number of equally spaced intermediate voltages that are selected by an analogue multiplexer providing the DAC output. As the analogue multiplexer increases in complexity with the number of DAC levels, this type of solution tends to become area-intensive for resolutions higher than 8 bits.

In such cases, coarse-fine architectures, also known as two-step architectures, or sub-ranging architectures offer a way to realize resistor string DACs efficiently. Such architectures resort to a coarse resistor string to generate a low resolution analogue representation, which is later refined by adding or subtracting the output of a fine resistor string, which is ideally covering a range equal to the coarse step, thus generating the final analogue value in a two-step approximation process. Such architecture implementations can be classified in two branches: passive and active, or un-buffered and buffered architectures.

In the first case (passive/un-buffered architecture), the fine resistor string is connected in parallel with a sub-set of the coarse string, providing a passive interpolation of its tap-to-tap voltage difference. This requires switch resistances to be taken into account, as well as loading effects, leading to nonlinearity, respectively differential nonlinearity (DNL) and integral nonlinearity (INL).

In a second case (active/buffered architecture), the coarse string is isolated from the second string by means of a buffer amplifier, making the network insensitive to switch resistance. It is also more scalable, as more outputs can be derived from a single coarse string. However, this architecture introduces offset, noise, and added complexity. FIG. 2 shows an example of the state of the art for the second category.

### SUMMARY

There are a number of problems associated with the known DAC 200 shown in FIG. 2. In the DAC of FIG. 2, two voltage buffers 210, 212 and two coarse switch trees 208a,b for the coarse selection are required. This is disadvantageous because switches and buffers dominate silicon area. In particular, a switch tree is very area intensive for modest resolution strings.

Furthermore, the offset of the two buffer amplifiers causes non-monotonicity. In the DAC of FIG. 2, at any coarse-code, looking at the output voltage at lowest and highest fine-code an offset is observed at the DAC output, that is respectively the offset of the bottom-end buffer 212 or the offset of the top-end buffer 210. This introduces a fine-code-dependent offset at the output (basically a weighted sum of the offsets of the two buffers, depending on the code). That is, the fine range is influenced by both buffer offsets. When a code is increased by 1 so that the next code-step requires changing the coarse-code, the fine code is reset to the lowest which could cause non-monotonicity e.g. if the top-buffer 210 has a positive offset and the bottom-buffer 212 has a negative offset (or in general if the offset difference is larger than a DAC step). In the DAC of FIG. 2 this is circumvented by using the top-buffer 210 always for the top-coarse-tap and the bottom buffer 212 always for the bottom-coarse-tap (resulting in the so-called “leap-frogging” tap selection).

There are applications where a multitude of DACs are required; such structure can be referred to as a cluster of DACs.

A cluster of DACs implemented with a state-of-the-art coarse-fine resistive architecture can benefit from a shared coarse stage, leading to significant savings in terms of area and power. On the other hand, each fine stage requires two independent voltage buffers or a circuitry to remove the loading effects, and two independent switch-trees for the coarse voltage selection.

As an example, a cluster of 10 DACs would require 20 voltage buffers, 20 coarse switch-trees and 10 fine switch-trees. Assuming that the area footprint for high resolution strings (somewhere >8 bits) is asymptotically dominated by the switch area, this circuitry would be limited by the switch area and would contain a large array of voltage buffers, contributing substantially to area and power consumption.

According to an aspect of the present disclosure there is provided a digital to analogue voltage converter comprising: a first resistor string having a plurality of resistors between a first end of the first resistor string and a second end of the first resistor string; and a plurality of digital to analogue voltage converter stages, each digital to analogue voltage converter stage coupled to said first resistor string and comprising: a voltage buffer; a first switching stage coupled to the first resistor string, the first switching stage configured to provide an input to the voltage buffer in dependence on receiving a first sub-word of a digital input of the digital to analogue voltage converter; a second resistor string having one or more resistors, wherein a first end of the second resistor string is coupled to a second transconductor and a second end of the second resistor string is coupled to an output of the voltage buffer; and a second switching stage coupled to the second resistor string, the second switching stage configured to provide an analogue voltage as an output of the digital to analogue voltage converter stage in dependence on receiving a second sub-word of the digital input of the digital to analogue voltage converter.

By having a single coarse switch tree (first switching stage) and a single voltage buffer, embodiments of the present disclosure provide significant size advantages by incurring less active area (especially when a cluster of DACs is considered). Furthermore, the complexity and power consumption of the DAC according to embodiments of the present disclosure is advantageously reduced.

Moreover, requiring only one buffer and one switch-tree (first switching stage) to select the coarse string output, leads to an asymptotical resolution advantage of 1 bit, in a high-resolution implementation, compared to the state of the art. If area is limited by the switches, in the same area one could fit twice the switches, which in the same asymptotic conditions result in an additional bit of resolution).

By having a single voltage buffer, reduced circuit noise is achieved.

Furthermore, in embodiments of the present disclosure buffer offset associated with the voltage buffer does not introduce non-monotonicity into the DAC. In contrast to the DAC of FIG. 2, in embodiments of the present disclosure the upper offset is removed and the fine range is defined by the current source which can be designed accurately. Therefore a constant offset associated with the single voltage buffer is observed as long as this is code independent.

In some implementations, the digital to analogue voltage converter comprises a first transconductor controlled by an input voltage and coupled to the first resistor string, and the current source is a second transconductor controlled by said input voltage such that the first transconductor delivers a current to the first resistor string that is proportional to a current delivered by the second transconductor to the second resistor string. More generally, the ratio between the current delivered by the first current source device and the current delivered by the second current source device may be constant.

Matching the current sources (the first transconductor and the second transconductor) is desired to match the fine range of the second resistor string to the coarse tap of the first resistor string. In this way, the steps of the digital to analogue voltage converter are tightly controlled and predictable. If this is not the case, a non-monotonicity in the DAC characteristic could be introduced.

In some implementations, the current delivered by the first transconductor and the current delivered by the second transconductor are the same.

In some implementations, the first transconductor comprises a p-type transistor, and the second transconductor comprises a p-type transistor. In these implementations, a gate terminal of the first transconductor may be arranged to receive the input voltage and a drain terminal of the first transconductor may be coupled to the first end of the first resistor string; and a gate terminal of the second transconductor may be arranged to receive the input voltage and a drain terminal of the second transconductor may be coupled to the first end of the second resistor string. The digital to analogue voltage converter may comprise a first reference voltage buffer comprising a voltage amplifier and the first transconductor, wherein the voltage amplifier may be arranged to receive a first reference voltage as an input, wherein an output terminal of the voltage amplifier is coupled to the gate terminal of the first transconductor to supply the input voltage to the first transconductor. The digital to analogue voltage converter may comprise a second reference voltage buffer arranged to receive a second reference voltage as an input, wherein an output terminal of the second reference voltage buffer is coupled to the second end of the first resistor string.

In other implementations, the first transconductor comprises an n-type transistor (313a), and the second transconductor comprises an n-type transistor (313b). In these implementations, a gate terminal of the first transconductor may be arranged to receive the input voltage and a drain terminal of the first transconductor may be coupled to the second end of the first resistor string; and a gate terminal of the second transconductor may be arranged to receive the input voltage and a drain terminal of the second transconductor may be coupled to the first end of the second resistor string. The digital to analogue voltage converter may comprise a first reference voltage buffer arranged to receive the input voltage as an input, wherein an output terminal of the first reference voltage buffer is coupled to the first end of the first resistor string. The digital to analogue voltage converter may comprise a second reference voltage buffer comprising a voltage amplifier and the first transconductor, wherein the voltage amplifier is arranged to receive the second reference voltage as an input, wherein an output terminal of the voltage amplifier is coupled to a gate terminal of the first transconductor.

In some implementations, the current source is not controlled by said input voltage and delivers a fixed current to the second resistor string. That is, the size of the digital to analogue voltage converter can be minimized as it does not utilize large devices that are required to matching the current sources and minimize the effect of random mismatch.

The first resistor string may comprise a plurality of first voltage taps and the first switching stage comprises a plurality of switches, each of the plurality of switches of the first switching stage controllable to provide a voltage at one of the plurality of voltage taps as the input to the voltage buffer.

The second resistor string may comprise a plurality of second voltage taps and the second switching stage comprises a plurality of switches, each of the plurality of switches of the second switching stage controllable to provide a voltage at one of the plurality of voltage taps as the output of the digital to analogue voltage converter stage.

The first switching stage and the second switching stage can be (implemented as a tree) of any base or mixed bases. For example each of the first switching stage and the second switching stage can be binary, quaternal, octal, quaternal-binary, etc. Embodiments of the present disclosure are not limited to a particular type of coding in the first switching stage and the second switching stage.

In implementations, the voltage buffer is the only voltage buffer in each digital to analogue voltage converter stage.

According to another aspect of the present disclosure there is provided a photon counting circuit, comprising: a photon detector having a photon sensitive area, the photon detector being configured to generate a current signal in dependence on an impact of a photon on the photon sensitive area; front-end electronic circuitry to receive the current signal and to provide a voltage signal in response to the current signal; an energy discriminator being connected to the front-end electronic circuitry, the energy discriminator being configured to generate a digital signal in dependence on a comparison of a level of the voltage signal with multiple threshold values, and the digital to analogue voltage converter according to embodiments described herein, the digital to analogue voltage converter coupled to the energy discriminator, wherein the output of each digital to analogue voltage converter stage provides a respective one of said multiple threshold values.

According to another aspect of the present disclosure there is provided a device for medical diagnostics, comprising a photon counting circuitry described herein, wherein the device is configured as an X-ray apparatus or a computed tomography scanner.

These and other aspects will be apparent from the embodiments described in the following. The scope of the present disclosure is not intended to be limited by this summary nor to implementations that necessarily solve any or all of the disadvantages noted.

### BRIEF DESCRIPTION OF THE DRAWINGS

In the drawings, like reference characters generally refer to the same parts throughout the different views. The drawings are not necessarily to scale, emphasis instead generally being placed upon illustrating the principles disclosed herein. Some embodiments of the disclosure will now be described by way of example only and with reference to the accompanying drawings, in which:

FIG. 1 illustrates a photo counting circuit including a digital to analogue voltage converter;

FIG. 2 illustrates a known digital to analogue voltage converter circuit;

FIG. 3a illustrates a digital to analogue voltage converter circuit according to one embodiment of the present disclosure;

FIG. 3b illustrates a digital to analogue voltage converter circuit according to one embodiment of the present disclosure;

FIG. 4 illustrates first and second transconductors used in the digital to analogue voltage converter according to embodiments of the present disclosure;

FIGS. 5a-c illustrate example switch-tree architectures that may be employed in the first switching stage and the second switching stage of the digital to analogue voltage converter according to embodiments of the present disclosure;

FIG. 6a illustrates a digital to analogue voltage converter circuit comprising a plurality of digital to analogue voltage converter stages;

FIG. 6b illustrates a digital to analogue voltage converter circuit comprising a plurality of digital to analogue voltage converter stages configured according to a specific implementation; and

FIG. 7 is a schematic block diagram of a device for medical diagnostics.

### DETAILED DESCRIPTION

Specific embodiments will now be described with reference to the drawings.

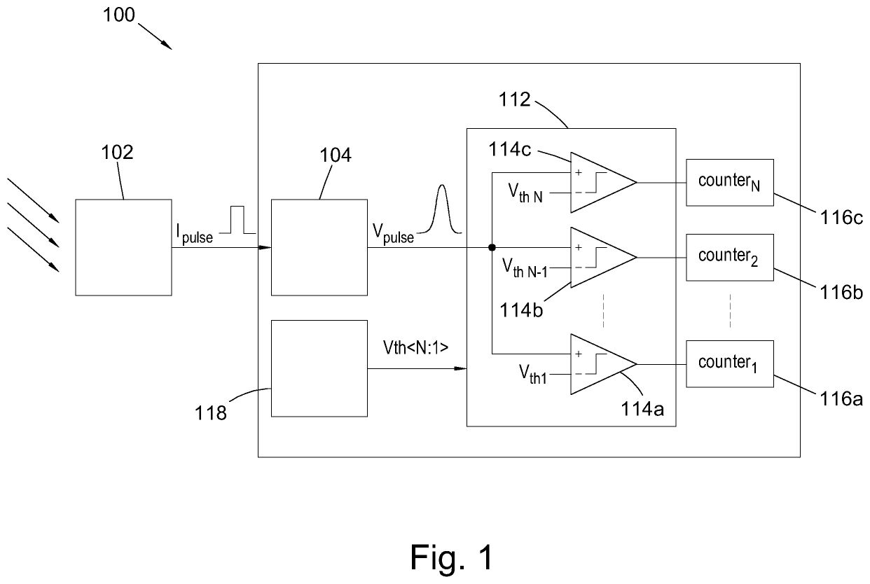

FIG. 1 illustrates a photo counting circuit 100 including a digital to analogue voltage converter.

Referring to FIG. 1, the photon counting circuit 100 comprises a photon detector 102 having a photon sensitive area. The photon detector 102 is configured to generate a current signal Iₚᵤₗₛₑ in dependence on an impact of a photon on the photon sensitive area. The photon counting circuit 100 comprises a front-end circuit stage 104 to receive the current signal Iₚᵤₗₛₑ from the photon detector 102 and to provide the voltage signal Vₚᵤₗₛₑ in response to the current signal. The front-end circuit stage 104 may comprise a charge sensitive amplifier. The inverting input of charge sensitive amplifier may receive the current signal I_{det}. A feedback capacitor may be connected between the inverting input of the charge sensitive amplifier and the output of the charge sensitive amplifier. A feedback resistor may be connected between the inverting input of the charge sensitive amplifier and the output of the charge sensitive amplifier. The front-end circuit stage 104 may comprise a shaping amplifier stage (not shown), to receive the output of the charge sensitive amplifier and output the voltage signal Vₚᵤₗₛₑ such that the voltage signal Vₚᵤₗₛₑ output by the front-end circuit stage 104 produces bell-shaped pulses.

The photon counting circuit 100 comprises an energy discriminator 112 being connected to the front-end circuit stage 104. In particular, the front-end circuit stage 104 provides the voltage signal Vₚᵤₗₛₑ to the energy discriminator 112.

The energy discriminator 112 is configured to generate a digital signal in dependence on a comparison of a level of the voltage signal Vₚᵤₗₛₑ with at least one threshold value Vth1, . . . , Vthn. In particular, the energy discriminator 112 may comprise several comparators 114 with different thresholds Vth1, . . . , VthN−1, VthN. The output signals of the comparators 114 are then individually counted by counters 116. It will be appreciated that the energy discriminator 112 may comprise any number of comparators (each with an associated counter).

As shown in FIG. 1, the photon counting circuit 100 comprises a digital to analogue voltage converter 118 used to provide the different threshold voltages Vth1, . . . , VthN−1, VthN of the comparators 114 of the energy discriminator 112.

The photon counting circuit 100 may be used for various photon counting applications, especially those which require low noise intensity measurements and possibly also spectral information. This includes medical imaging, spectroscopy, security scanners, computed tomography, etc.

The digital to analogue voltage converter described herein may be used in, but is not limited to use in, the digital to analogue voltage converter stage 118 of the photon counting circuit 100 shown in FIG. 1.

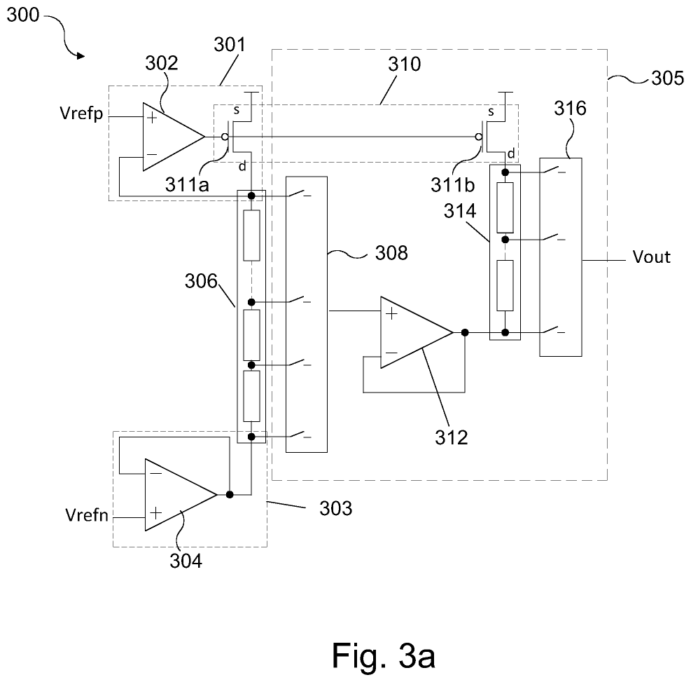

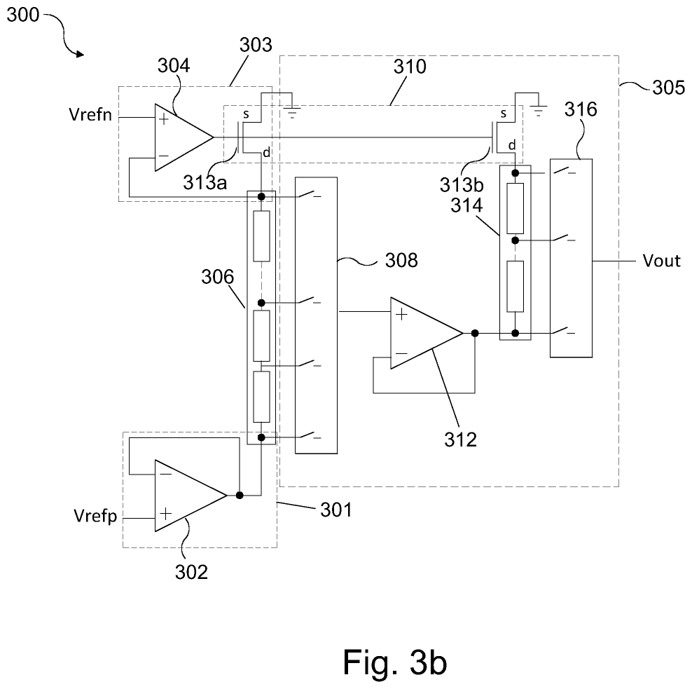

Reference is now made to FIG. 3a which illustrates a digital to analogue voltage converter circuit 300 according to one embodiment of the present disclosure.

The digital to analogue voltage converter circuit 300 shown in FIG. 3a comprises a first reference voltage buffer 301 which comprises a first voltage amplifier 302 and a first transconductor 311a. In the example of FIG. 3a, the first transconductor 311a is a p-type transistor however as discussed in more detail below, this is merely an example.

The first voltage amplifier 302 is arranged to receive a first reference voltage (Vrefp) as an input. An output terminal of the first voltage amplifier 302 is coupled to the gate terminal of the p-type transistor 311a to supply an input voltage to the p-type transistor 311a. The first reference voltage (Vrefp) may be a positive voltage.

The first voltage amplifier 302 may be an operational amplifier arranged to receive the first reference voltage (Vrefp) at its non-inverting input, with the inverting input of the operational amplifier being coupled to the drain terminal of the p-type transistor 311a.

The drain terminal of the p-type transistor 311a is coupled to a first end of a first resistor string 306 and the source terminal of the p-type transistor 311a is coupled to a supply voltage. The term “resistor string” is used herein to refer to one or more resistors connected in series. The first resistor string 306 comprises a plurality of resistors and operates as a coarse resistor string. The p-type transistor 311a provides a current I_{coarse} to the first resistor string 306. The terms “coarse” and “fine” referred to herein in relation to a resistor string refer to the voltage step, or resolution, across each resistor of the resistor string and not to their resistive value.

As noted above, the gate terminal of the p-type transistor 311a is connected to the output terminal of the first voltage amplifier 302 forming a regulation loop which sets voltage at the first end of the resistor string 306 and at the same time the string current I_{coarse} delivered to the resistor string 306. The voltage at the first end of the resistor string 306 may not be the first reference voltage (Vrefp), but an approximation of it, or in general, a voltage that depends on the first reference voltage (Vrefp).

The digital to analogue voltage converter circuit 300 shown in FIG. 3a comprises a second reference voltage buffer 303. The second reference voltage buffer 303 shown in FIG. 3a comprises a second voltage amplifier 304. The second voltage amplifier 304 is arranged to receive a second reference voltage (Vrefn) as an input. The second reference voltage (Vrefn) may be a negative voltage. An output terminal of the second voltage amplifier 304 is coupled to a second end of the first resistor string 306 (that is the opposite end to the first end). The voltage at the second end of the resistor string 306 may not be the second reference voltage (Vrefn), but an approximation of it, or in general, a voltage that depends on the second reference voltage (Vrefn). The second voltage amplifier 304 may be an operational amplifier arranged to receive the second reference voltage (Vrefn) at its non-inverting input, with the inverting input of the operational amplifier being coupled to its output at the second end of the first resistor string 306. That is, the second reference voltage buffer 303 may comprise a feedback loop. It will be appreciated that the second reference voltage buffer 303 shown in FIG. 3a is merely an example and it may be constructed differently to that shown in FIG. 3a.

The second reference voltage (Vrefn) is lower than the first reference voltage (Vrefp) such that there is a potential difference across the first resistor string 306. The plurality of resistors in the first resistor string 306 may be of equal resistance value so that the potential difference is divided across the first resistor string 306 in equal steps. However this is not required, and the plurality of resistors in the first resistor string 306 may not have the same resistance values so that the potential difference is divided across the first resistor string 306 in non-linear steps.

In a variant of the digital to analogue voltage converter circuit 300 shown in FIG. 3a in some implementations, the first voltage amplifier 302 is not present and the gate terminal of the p-type transistor 311a directly receives the first reference voltage (Vrefp). Similarly, the second voltage amplifier 304 may not be present and the second end of the first resistor string 306 may directly receive the second reference voltage (Vrefn).

As shown in FIG. 3a the digital to analogue voltage converter circuit 300 comprises one or more digital to analogue voltage converter stage 305.

Each digital to analogue voltage converter stage 305 comprises a first switching stage (a coarse switch tree) 308 that is coupled to the first resistor string 306. In particular, the first resistor string 306 comprises a plurality of voltage taps (a contact that can be reached by the first switching stage 308) and the first switching stage 308 comprises a plurality of switches, each of the plurality of switches of the first switching stage 308 are controllable to connect to one of the voltage taps of the first resistor string 306.

The first resistor string 306 comprises a voltage tap at the first end of the first resistor string 306, this voltage tap is coupled to the drain terminal of the p-type transistor 311a. The first resistor string 306 also comprises a voltage tap between each of the resistors in the first resistor string 306. The first resistor string 306 also comprises a voltage tap at the second end of the first resistor string 306, this voltage tap is coupled to the output of the second voltage amplifier 304.

The first switching stage 308 is configured to provide an input to a voltage buffer 312 in dependence on receiving a first sub-word of a digital input of the digital to analogue voltage converter. In particular, in dependence on receiving the first sub-word of the digital input the first switching stage 308 is configured to close one or more of its switches and supply the voltage at the corresponding voltage tap of the first resistor string 306 to the input of the voltage buffer 312.

The first sub-word corresponds to the most significant bits of the digital input that is to be converted to an analogue voltage. For example, for an 8 bit digital input and the first switching stage 308 having 32 levels, the first sub-word would be 5 bits in length (b7-b3, where b7 is the most significant bit of the 8 bit digital input).

The voltage buffer 312 may be an operational amplifier arranged to receive an input voltage from the first switching stage 308 at its non-inverting input, with the inverting input of the operational amplifier being coupled to its output.

Each digital to analogue voltage converter stage 305 comprises a current source 311b which provides a current I_{fine} to a second resistor string 314. The current source 311b may be a second transconductor or a fixed current source (not controlled).

In embodiments where the current source 311b is a fixed current source, the first transconductor 311a is not required (the first resistor string 306 is connected directly to the first reference voltage and the second reference voltage, which may be buffered). That is, a first end of the first resistor string 306 is coupled directly to the first reference voltage (Vrefp) or an output of the first reference voltage buffer 301 comprising the voltage amplifier 302, and a second end of the first resistor string 306 is coupled to the second reference voltage (Vrefn) or an output of the second reference voltage buffer 303 comprising the voltage amplifier 304. In embodiments where the current source 311b is a fixed current source the current source 311b is not controlled by the input voltage supplied by the output terminal of the first voltage amplifier 302, and delivers a fixed current to the second resistor string 314.

FIG. 3a shows the current source 311b as a second transconductor in that it is controlled by the input voltage supplied by the output terminal of the first voltage amplifier 302. That is, the digital to analogue voltage converter circuit 300 shown in FIG. 3a comprises a pair 310 of matched current sources. In particular, the current I_{fine} delivered by the second transconductor 311b to second resistor string 314 may be proportional to the current I_{coarse} delivered by the first transconductor 311a to the first resistor string 306. In some implementations the current I_{fine} is the same as the current I_{coarse}.

In the example of FIG. 3a, the second transconductor 311b is a p-type transistor however as discussed in more detail below, this is merely an example. The output terminal of the first voltage amplifier 302 is coupled to the gate terminal of the p-type transistor 311b to supply an input voltage to the p-type transistor 311b.

The drain terminal of the p-type transistor 311b is coupled to a first end of the second resistor string 314 and the source terminal of the p-type transistor 311b is coupled to a supply voltage. The second resistor string 314 comprises one or more resistors and operates as a fine resistor string. The output terminal of the voltage buffer 312 is coupled to a second end of the second resistor string 314 (that is the opposite end to the first end).

In implementations where the second resistor string 314 comprises a plurality of resistors, the plurality of resistors in the second resistor string 314 may be of equal resistance value so that the potential difference across the second resistor string 314 is divided across the second resistor string 314 in equal steps. However this is not required, and the plurality of resistors in the second resistor string 314 may not have the same resistance values so that the potential difference is divided across the second resistor string 314 in non-linear steps.

Each digital to analogue voltage converter stage 305 comprises a second switching stage (a fine switch tree) 316 that is coupled to the second resistor string 314. In particular, the second resistor string 314 comprises a plurality of voltage taps (a contact that can be reached by the second switching stage 316) and the second switching stage 316 comprises a plurality of switches, each of the plurality of switches of the first switching stage 308 are controllable to connect to one of the voltage taps of the second resistor string 314.

The second resistor string 314 comprises a voltage tap at the first end of the second resistor string 314, this voltage tap is coupled to the drain terminal of the p-type transistor 311a. The second resistor string 314 also comprises a voltage tap at the second end of second resistor string 314, this voltage tap is coupled to the output of the voltage buffer 312.

If the second resistor string 314 comprises a plurality of resistors, the second resistor string 314 also comprises a voltage tap between each of the resistors in the second resistor string 314.

The second switching stage 316 is configured to provide an analogue output voltage Vₒᵤₜ of the digital to analogue voltage converter stage 305 in dependence on receiving a second sub-word of a digital input of the digital to analogue voltage converter. In particular, in dependence on receiving the second sub-word of the digital input the second switching stage 316 is configured to close one or more of its switches and supply the voltage at the corresponding voltage tap of the second resistor string 314 as an analogue output voltage Vₒᵤₜ of the digital to analogue voltage converter stage 305.

The second sub-word corresponds to the least significant bits of the digital input that is to be converted to an analogue voltage. For example, for an 8 bit digital input and the second switching stage 316 having 8 levels, the second sub-word would be 3 bits in length (b2-b0, where b0 is the least significant bit of the 8 bit digital input).

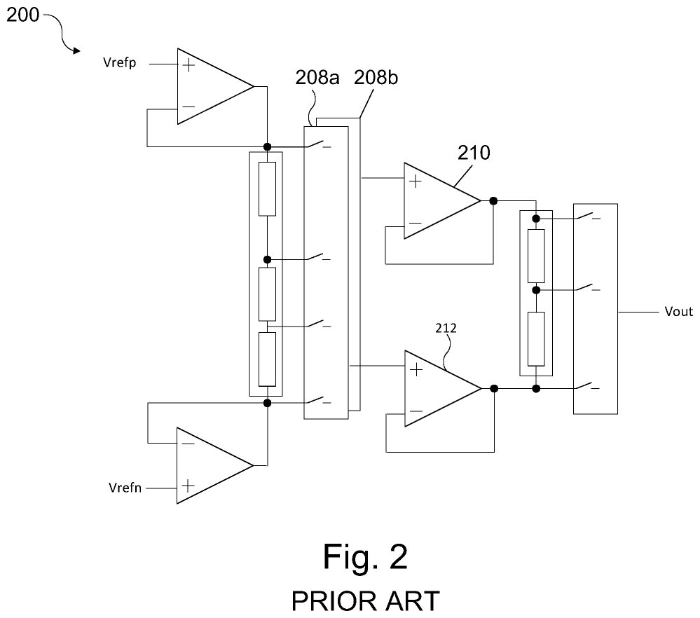

In contrast to the known DAC 200 shown in FIG. 2, in the digital to analogue voltage converter circuit 300 each digital to analogue voltage converter stage 305 requires only a single first switching stage (a coarse switch tree) 308 and a single voltage buffer 312.

With reference to the above described embodiments, considering a coarse resistor string 306 comprising N resistors and a fine resistor string 314 comprising K resistors (with K+1 voltage taps), the output of the digital to analogue voltage converter stage 305, Vₒᵤₜ, is given by V_{coarse}+V_{fine}. If all voltage taps are equally spaced, the constraints in this system may be so defined:

(Vrefp−Vrefn)=NR_{coarse}I_{coarse}

In order for the fine range to fit in the coarse step,

R_{coarse}I_{coarse}=(K+1)R_{fine}I_{fine}.

e.g. if K=7 and R_{fine}=R_{coarse}/8, the fine range fits in the coarse step.

R_{coarse} and R_{fine} can be realized using the same unit element, for matching purpose. I_{coarse} and I_{fine} are matched but a scaling factor between them can be foreseen, as long as the equality holds.

The digital to analogue voltage converter circuit 300 can be considered a “global DAC”, because the digital to analogue voltage converter circuit 300 comprise another DAC (each digital to analogue voltage converter stage 305). In the presence of mismatch (which can be caused in production due to devices have randomly distributed parameters), the coarse string unit 306 requires the same matching of the global DAC, or log₂(NK) bits, in order to fulfil the respective integral nonlinearity (INL) specification. Since we resolve the resolution of the digital to analogue voltage converter circuit 300 in two steps of N and K substeps, the global DAC has N*K steps.

The fine string matching is required to fulfil the global DAC differential non-linearity (DNL) and the fine range gain error, which results in a DNL error in transitions from the fine full-scale to the following coarse step. Each step in the stairs (produced by the global DAC when subsequent codes are selected) should not depart in value by more than say 0.5 of its nominal value (the use of 0.5 referred to here is often used if a certain DNL is required, but it will be appreciated that this particular value is merely an example). If this is not true this may cause a missing code or even a non-monotonicity. Since there is a coarse-fine transition, some steps in the stairs are special because they result from a coarse transition. In this case the fine DAC range has to be accurate in order to not create again missing codes or even non-monotonicity in that transition.

For this worst case DNL transition to be within half an LSB it must apply:

|R_{coarse}I_{coarse}−KR_{fine}I_{fine}|<0.5R_{coarse}I_{coarse}/K

If R_{coarse}=R=KR_{fine} and I_{fine}=I, with mismatch in the fine string and current:

$$\vert RI - ( R + d ) ( I + dI ) \vert < \frac{0.5}{K} RI \\ \vert 1 - ( 1 + dR / R ) ( 1 + dI / I ) \vert < \frac{0.5}{K} \\ \vert \frac{dR}{R} + \frac{dI}{I} + \frac{dRdI}{RI} \vert < \frac{0.5}{K} \\ If \frac{dR}{R} << \frac{dI}{I} : \\ \vert \frac{dI}{I} \vert < \frac{0.5}{K}$$

As an example, if the fine unit is made of 16 parallel coarse units, the fine string mismatch is in fact non-dominant, and the allowed relative current mismatch between the strings is:

$$\vert \frac{dI}{I} \vert < \frac{0.5}{16} = 3.125 \%$$

Whilst we refer above to the first transconductor 311a and the second transconductor 311b as being p-type transistors this is merely an example. In the example digital to analogue voltage converter circuit 300 shown in FIG. 3b, the first transconductor 311a and the second transconductor 311b are n-type transistors.

As shown in FIG. 3b the first reference voltage buffer 301 comprises the first voltage amplifier 302 (with no transconductor). The first voltage amplifier 302 is arranged to receive the first reference voltage (Vrefp) as an input. An output terminal of the first voltage amplifier 302 is coupled to a first end of the first resistor string 306. The first voltage amplifier 302 may be an operational amplifier arranged to receive the second reference voltage (Vrefn) at its non-inverting input, with the inverting input of the operational amplifier being coupled to its output at the first end of the first resistor string 306. That is, the first reference voltage buffer 301 may comprise a feedback loop. It will be appreciated that the first reference voltage buffer 301 shown in FIG. 3b is merely an example and it may be constructed differently to that shown in FIG. 3b.

As shown in FIG. 3b, the second reference voltage buffer 303 comprises the second voltage amplifier 304 and a first transconductor 313a in the form of an n-type transistor. The second voltage amplifier 304 is arranged to receive the second reference voltage (Vrefn) as an input. An output terminal of the second voltage amplifier 304 is coupled to the gate terminal of the n-type transistor 313a to supply an input voltage to the n-type transistor 313a. The source terminal of the n-type transistor 313a is coupled to ground and the drain terminal of the n-type transistor 313a is coupled to a second end of a first resistor string 306 (that is the opposite end to the first end).

FIG. 3b shows the current source 313b as a second transconductor in the form of an n-type transistor that it is controlled by the input voltage supplied by the output terminal of the second voltage amplifier 304. In particular, the output terminal of the second voltage amplifier 304 is coupled to the gate terminal of the n-type transistor 313b to supply an input voltage to the n-type transistor 313b. The source terminal of the n-type transistor 313b is coupled to ground and the drain terminal of the n-type transistor 313b is coupled to the first end of the second resistor string 314. As in FIG. 3a, in the example of FIG. 3b the output terminal of the voltage buffer 312 is coupled to a second end of the second resistor string 314 (that is the opposite end to the first end).

In a variant of the digital to analogue voltage converter circuit 300 shown in FIG. 3b in some implementations, the second voltage amplifier 304 is not present and the gate terminal of the n-type transistor 313a directly receives the second reference voltage (Vrefn). Similarly, the first voltage amplifier 302 may not be present and the first end of the first resistor string 306 directly receives the first reference voltage (Vrefp).

Furthermore, the current source 313b may be a fixed current source (not controlled). In embodiments where the current source 311b is a fixed current source, the first transconductor 313a is not required (the first resistor string 306 is connected directly to the first reference voltage and the second reference voltage, which may be buffered). In embodiments where the current source 313b is a fixed current source the current source 313b is not controlled by the input voltage supplied by the output terminal of the second voltage amplifier 304, and delivers a fixed current to the second resistor string 314.

It can be seen from both FIGS. 3a and 3b that in embodiments of the present disclosure the extrapolation from a single voltage tap only requires 1 voltage buffer (voltage buffer 312) and 1 switch-tree (the first switching stage 308) providing significant circuit area savings compared to the known DAC shown in FIG. 2.

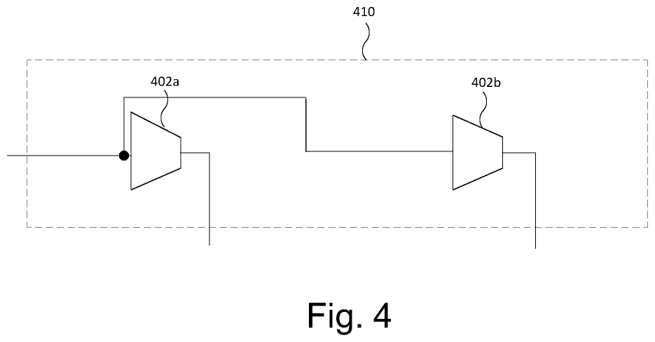

FIG. 4 illustrates a generalised version of a pair 410 of matched transconductors 402a,402b which may be used in the digital to analogue voltage converter circuit 300 shown in FIG. 3a or FIG. 3b. Whilst we have referred to these matched transconductors 402a,402b as being either p-type or n-type transistors, embodiments extend to other implementations of the transconductors 402a,402b which are configured to operate as current sources and deliver the coarse (I_{coarse}) and fine (I_{fine}) string currents that have a relationship described herein. As shown in FIG. 4, the first transconductor 402a and the second transconductor 402a are controlled by the same input voltage.

In all embodiments, a digital code is used to control the switch-trees (i.e. the first switching stage 308 and the second switching stage 316). Given a digital word in any coding, a least significant sub-set is used to decode the fine switch-tree (second switching stage 316), while the most significant sub-set is used to decode the coarse switch-tree (first switching stage 308).

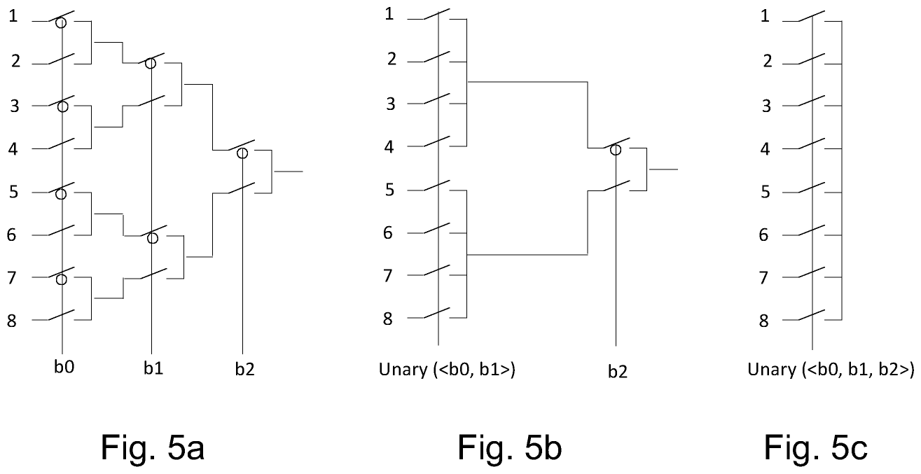

Both the first switching stage 308 and the second switching stage 316 can be (implemented as a tree) of any base or mixed bases. Examples are given in FIG. 5 in the simplified case of the second switching stage 316 having 8 levels and receiving a least significant sub-word of a digital input of the digital to analogue voltage converter circuit 300 of 3 bits, it will be appreciated that the number of levels shown in FIG. 5a-c is merely an example. Furthermore these examples are also applicable to the first switching stage 308.

FIG. 5a illustrates the example second switching stage 316 as a binary switch tree. FIG. 5b illustrates the example second switching stage 316 as a quaternal-binary switch tree. FIG. 5c illustrates the example second switching stage 316 as an octal switch tree.

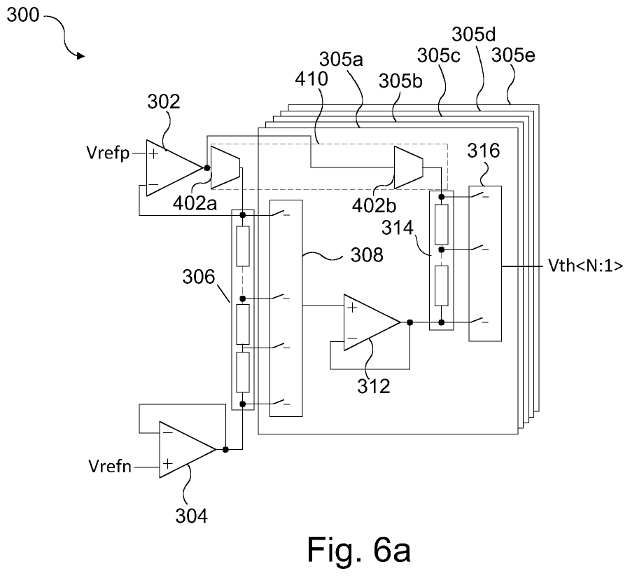

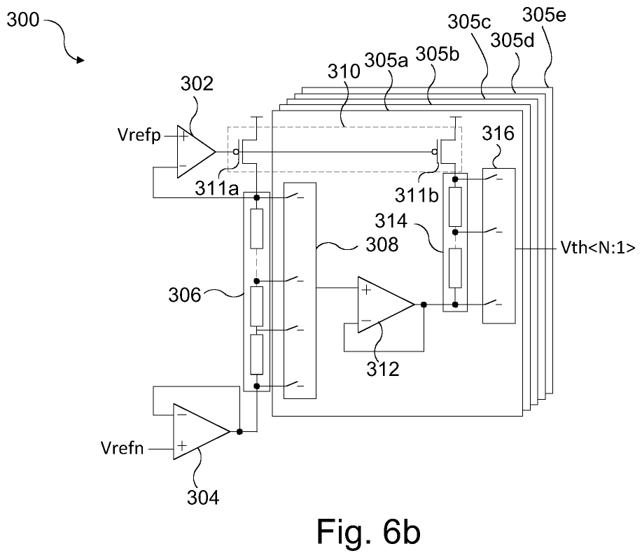

FIG. 6a illustrates the digital to analogue voltage converter circuit 300 comprising a plurality of digital to analogue voltage converter stages 305a-e with each digital to analogue voltage converter stages 305a-e providing an analogue output voltage Vth in dependence on the digital input supplied to the first switching stage 308 and the second switching stage 316 of the particular digital to analogue voltage converter stages 305a.

As will be apparent, each of the digital to analogue voltage converter stages 305a-e are coupled to the same first transconductor 402a and the same first resistor string 306. Expressed another way, the first transconductor 402a and the first resistor string 306 are common to each of the digital to analogue voltage converter stages 305a-e

FIG. 6a illustrates an example implementation of a pair 410 of matched transconductors 402a, 402b (whereby the current I_{fine} delivered by the second transconductor 402b is proportional to the current I_{coarse} delivered by the first transconductor 402a).

FIG. 6b illustrates a digital to analogue voltage converter circuit 300 corresponding to FIG. 6a where the matched transconductors 402a, 402b are p-type transistors.

Embodiments of the present disclosure also extend to a digital to analogue voltage converter circuit 300 comprising a plurality of digital to analogue voltage converter stages utilising n-type transistors as the matched transconductors 402a, 402b

It will be appreciated that the digital to analogue voltage converter circuit 300 shown in FIGS. 6a and 6b could be employed in the digital to analogue voltage converter stage 118 of the photon counting circuit 100 shown in FIG. 1 to provide the different threshold voltages Vth1, . . . , VthN−1, VthN of the comparators 114 of the energy discriminator 112.

In the examples of FIGS. 6a and 6b a pair of matched transconductors is used however as noted above, the second transconductor could be a fixed current source.

It will be appreciated that the number of digital to analogue voltage converter stages 305a-e shown in FIGS. 6a and 6b is merely an example.

It will be apparent from FIGS. 6a and 6b that the embodiments of the present disclosure scale well with respect to circuit area and power consumption, compared to the known DAC shown in FIG. 2.

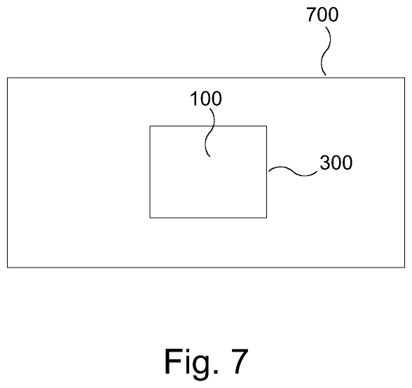

FIG. 7 shows an example of an application where a photon counting circuit 100 comprising the digital to analogue voltage converter circuit 300 according to an embodiment described herein is provided in a device 700 for medical diagnostics. The device 700 may be configured, for example, as an X-ray apparatus or a computed tomography scanner.

Although the disclosure has been described in terms of embodiments as set forth above, it should be understood that these embodiments are illustrative only and that the claims are not limited to those embodiments. Those skilled in the art will be able to make modifications and alternatives in view of the disclosure which are contemplated as falling within the scope of the appended claims. Each feature disclosed or illustrated in the present specification may be incorporated in any embodiments, whether alone or in any appropriate combination with any other feature disclosed or illustrated herein.

### LIST OF REFERENCE NUMERALS

100 photon counting circuit
102 photon detector
104 front-end circuit stage
112 energy discriminator
114 comparator
116 counter
118 digital to analogue voltage converter
200 known digital to analogue voltage converter
208a,b coarse switch tree
210 voltage buffer
212 voltage buffer
300 digital to analogue voltage converter circuit
301 first reference voltage buffer
302 first voltage amplifier
303 second reference voltage buffer
304 second voltage amplifier
305 digital to analogue voltage converter stage
306 first resistor string
308 first switching stage
310 pair of matched current sources
311a p-type transistor
311b p-type transistor
312 voltage buffer
313a n-type transistor
313b n-type transistor
314 second resistor string
316 second switching stage
402a first transconductor
402b second transconductor
410 pair of matched transconductors
700 device

What is claimed is:

1. A digital to analogue voltage converter comprising:
a first resistor string having a plurality of resistors between a first end of the first resistor string and a second end of the first resistor string;
and
a plurality of digital to analogue voltage converter stages, each digital to analogue voltage converter stage coupled to said first resistor string and comprising:
a voltage buffer;
a first switching stage coupled to the first resistor string, the first switching stage configured to provide an input to the voltage buffer in dependence on receiving a first sub-word of a digital input of the digital to analogue voltage converter;
a second resistor string having one or more resistors, wherein a first end of the second resistor string is coupled to a current source and a second end of the second resistor string is coupled to an output of the voltage buffer; and
a second switching stage coupled to the second resistor string, the second switching stage configured to provide an analogue voltage as an output of the digital to analogue voltage converter stage in dependence on receiving a second sub-word of the digital input of the digital to analogue voltage converter.

2. The digital to analogue voltage converter of claim 1, wherein the digital to analogue voltage converter comprises a first transconductor controlled by an input voltage and coupled to the first resistor string, and the current source is a second transconductor controlled by said input voltage such that the first transconductor delivers a current to the first resistor string that is proportional to a current delivered by the second transconductor to the second resistor string.

3. The digital to analogue voltage converter of claim 2, wherein the current delivered by the first transconductor and the current delivered by the second transconductor are the same.

4. The digital to analogue voltage converter of claim 2, wherein the first transconductor comprises a p-type transistor, and the second transconductor comprises a p-type transistor.

5. The digital to analogue voltage converter of claim 4, wherein:
a gate terminal of the first transconductor is arranged to receive the input voltage and a drain terminal of the first transconductor is coupled to the first end of the first resistor string; and
a gate terminal of the second transconductor is arranged to receive the input voltage and a drain terminal of the second transconductor is coupled to the first end of the second resistor string.

6. The digital to analogue voltage converter of claim 5, comprising:
a first reference voltage buffer comprising a voltage amplifier and the first transconductor, wherein the voltage amplifier is arranged to receive a first reference voltage as an input, wherein an output terminal of the voltage amplifier is coupled to the gate terminal of the first transconductor to supply the input voltage to the first transconductor.

7. The digital to analogue voltage converter of claim 5, comprising: a second reference voltage buffer arranged to receive a second reference voltage as an input, wherein an output terminal of the second reference voltage buffer is coupled to the second end of the first resistor string.

8. The digital to analogue voltage converter of claim 2, wherein the first transconductor comprises an n-type transistor, and the second transconductor comprises an n-type transistor.

9. The digital to analogue voltage converter of claim 8, wherein:
a gate terminal of the first transconductor is arranged to receive the input voltage and a drain terminal of the first transconductor is coupled to the second end of the first resistor string; and
a gate terminal of the second transconductor is arranged to receive the input voltage and a drain terminal of the second transconductor is coupled to the first end of the second resistor string.

10. The digital to analogue voltage converter of claim 9, comprising:
a first reference voltage buffer arranged to receive the input voltage as an input, wherein an output terminal of the first reference voltage buffer is coupled to the first end of the first resistor string.

11. The digital to analogue voltage converter of claim 9, comprising:
a second reference voltage buffer comprising a voltage amplifier and the first transconductor, wherein the voltage amplifier is arranged to receive the second reference voltage as an input, wherein an output terminal of the voltage amplifier is coupled to a gate terminal of the first transconductor.

12. The digital to analogue voltage converter of claim 1, wherein the current source is not controlled by said input voltage and delivers a fixed current to the second resistor string.

13. The digital to analogue voltage converter of claim 12, wherein:
a first end of the first resistor string is coupled to a first reference voltage or an output of a first reference voltage buffer comprising a voltage amplifier, wherein the voltage amplifier is arranged to receive the first reference voltage as an input; and
a second end of the first resistor string is coupled to a second reference voltage or an output of a second reference voltage buffer comprising a voltage amplifier, wherein the voltage amplifier is arranged to receive the second reference voltage as an input, wherein the second reference voltage is lower than the first reference voltage.

14. The digital to analogue voltage converter of claim 1, wherein
the first resistor string comprises a plurality of first voltage taps and the first switching stage comprises a plurality of switches, each of the plurality of switches of the first switching stage controllable to provide a voltage at one of the plurality of voltage taps as the input to the voltage buffer; and
the second resistor string comprises a plurality of second voltage taps and the second switching stage comprises a plurality of switches, each of the plurality of switches of the second switching stage controllable to provide a voltage at one of the plurality of voltage taps as the output of the digital to analogue voltage converter stage.

15. The digital to analogue voltage converter of claim 1, wherein the voltage buffer is the only voltage buffer in each digital to analogue voltage converter stage.

16. A photon counting circuit, comprising:
a photon detector having a photon sensitive area, the photon detector being configured to generate a current signal in dependence on an impact of a photon on the photon sensitive area;
front-end electronic circuitry to receive the current signal and to provide a voltage signal in response to the current signal;
an energy discriminator being connected to the front-end electronic circuitry, the energy discriminator being configured to generate a digital signal in dependence on a comparison of a level of the voltage signal with multiple threshold values; and
the digital to analogue voltage converter according to claim 1, the digital to analogue voltage converter coupled to the energy discriminator, wherein the output of each digital to analogue voltage converter stage provides a respective one of said multiple threshold values.

17. A device for medical diagnostics, comprising a photon counting circuitry of claim 16, wherein the device is configured as an X-ray apparatus or a computed tomography scanner.
